(19) United States
(12) Patent Application Publication
(10) Pub. No.: US 2009/0321758 A1
(43) Pub. Date: Dec. 31, 2009

(54) LED WITH IMPROVED EXTERNAL LIGHT EXTRACTION EFFICIENCY

(76) Inventors: WEN-HUANG LIU, Guan-Xi Town 306 (TW); Chung-Che Dan, Banciao City (TW)

Correspondence Address: PATTERSON & SHERIDAN, L.L.P., 3040 POST OAK BOULEVARD, SUITE 1500, HOUSTON, TX, 77056, US

(21) Appl. No.: 12/146,142

(22) Filed: Jun. 25, 2008

(51) Int. Cl. H01L 33/00

(52) U.S. Cl. 257/98; 257/E33.061

(57) ABSTRACT

Light-emitting semiconductor devices are provided with certain layers in an effort to produce increased luminous intensity when compared to conventional light-emitting devices. The light-emitting semiconductor device includes a light-emitting semiconductor; a first transparent layer disposed over the light-emitting semiconductor; a first wavelength-converting layer disposed over the first transparent layer, wherein an upper surface of the wavelength-converting layer is curved; and a second transparent layer disposed over the wavelength-converting layer, wherein an upper surface of the second transparent layer is curved or tapered.

### BACKGROUND OF THE INVENTION

1. Field of the Invention

Embodiments of the present invention generally relate to light-emitting semiconductor devices and, more particularly, to packaging such devices with certain layers in an effort to increase light extraction from the light-emitting semiconductor.

2. Description of the Related Art

Many techniques exist to generate white light from semiconductor devices, such as light-emitting diodes (LEDs). Some of these include combining the outputs of individual red, green, and blue LEDs; combining a blue LED with yellow phosphor or a green and a red phosphor; and combining an ultraviolet LED with red, green, and blue phosphor. One technique involves employing a blue LED combined with a layer or coating of yellow phosphor, as disclosed in U.S. Pat. No. 5,998,925, entitled, “Light Emitting Device Having a Nitride Compound Semiconductor and a Phosphor Containing a Garnet Fluorescent Material,” and illustrated in FIG. 1.

FIG. 1 depicts a lead-type LED 100 where the light-emitting component 110 is installed on mount leads 150. An n-electrode and a p-electrode of the light-emitting component 110 are connected to the mount leads 150 via wire bond 120. A cup of the mount leads 150 is filled with a coating resin 130 that contains a specified phosphor to cover the light-emitting component 110. The leads 150, light-emitting component 110 and the coating resin 130 are encased in a molding material 140, which protects the light-emitting component 110 and may function as a lens to focus or diffuse the light emitted by the LED 100.

When the LED is forward biased, light emitted by the light-emitting component 110 excites the phosphor contained in the coating resin 130 to generate fluorescent light having a wavelength different from that of the light-emitting component's light. In this manner, the fluorescent light emitted by the phosphor and the light-emitting semiconductor's light that passes through the phosphor without contributing to the excitation of the phosphor are mixed and output. Thus, when the light-emitting component 110 employs a gallium nitride (GaN) compound semiconductor and the coating resin 130 includes a garnet phosphor activated with cerium, blue light is emitted from the light-emitting component 110, and some of the light excites the phosphor to produce yellow light. The blended combination of blue and yellow light essentially produces white light. However, the white light produced by such conventional light-emitting semiconductor devices employing a blue LED and a yellow phosphor exhibits a color ring phenomenon, where the periphery of the emitted light appears more yellow and the middle appears more blue.

U.S. Pat. No. 5,959,316 to Lowery, issued Sep. 28, 1999 and entitled, “Multiple Encapsulation of Phosphor-LED Devices,” depicts a conventional LED light 200 as illustrated in FIG. 2. In the LED light 200, an LED 210 is disposed on a lead frame 250, and a fluorescent material 240 is disposed over the LED 210. Wire bonds 220 may be connected to the LED 210 through the fluorescent material 240.

As another example, Lowery teaches an LED light 300 with an LED 310 held in a lead frame 350, as shown in FIG. 3. A transparent spacer 360 encapsulates the LED 310, and a level of fluorescent material 330 is disposed above the transparent spacer 360. Wire bonds 320 connected to the LED chip 310 protrude through the fluorescent material 330 and the transparent spacer 360.

In another embodiment from Lowery as illustrated in FIG. 4, an LED light 400 with a surface-mounted LED 410 is disposed on a device substrate 470 of a surface mount device. The LED 410 is encapsulated in a transparent spacer 460, which is further covered by a layer of fluorescent material 430 and a final transparent encapsulation layer 440. Wire bonds 420 are coupled from the LED 410 to the substrate 470. In both embodiments, the transparent spacers 360, 460 separate the LED from the fluorescent material in an effort to eliminate the annular rings.

As another example, a cross-section of a Philips Lumileds Luxeon LED 500 is illustrated in FIG. 5. The LED may have a light-emitting semiconductor 501 disposed on a substrate 510. A fluorescent-material-containing layer 503 may be disposed above the light-emitting semiconductor 501. A transparent encapsulation layer 504 may be disposed above the florescent-material-containing layer 503. Additionally, a wire bond 505 may be connected to the substrate 510 in this LED.

Light-emitting devices with greater luminous intensity for a given input power offer a competitive advantage. Accordingly, what is needed is an apparatus emitting light with increased luminous intensity when compared to conventional light-emitting devices.

### SUMMARY OF THE INVENTION

One embodiment of the present invention provides a light-emitting device. The light-emitting device generally includes a light-emitting semiconductor, a first transparent layer disposed over the light-emitting semiconductor, a first wavelength-converting layer disposed over the first transparent layer, wherein an upper surface of the wavelength-converting layer is curved, and a second transparent layer disposed over the wavelength-converting layer, wherein an upper surface of the second transparent layer is at least one of curved or tapered.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a prior art schematic cross-sectional view of a lead-type white light-emitting diode (LED) lamp.

FIG. 2 is a prior art schematic cross-sectional view of a surface mount LED light.

FIG. 3 is a prior art schematic cross-sectional view of a surface mount LED light with multiple encapsulation layers where an LED is encapsulated by a spacer and a flat layer of fluorescent material.

FIG. 4 is a prior art schematic cross-sectional view of a surface mount LED light with multiple encapsulation layers where an LED is encapsulated by a transparent layer and a curved layer of fluorescent material.

FIG. 5 is a prior art schematic cross-sectional view of a surface mount LED with multiple encapsulation layers where a light-emitting semiconductor is encapsulated by a dome of fluorescent material layer and a domed transparent layer.

FIGS. 6A and 6B illustrate a cross section of a light-emitting semiconductor encapsulated by a first domed transparent layer, a domed wavelength-converting layer, and a second domed transparent layer, according to embodiments of the present invention.

FIG. 7 is a color correlated temperature (CCT) graph that demonstrates increased luminous intensity of the embodiments of the invention over the prior art.

FIG. 8 illustrates a cross section of a light-emitting semiconductor encapsulated by a first domed transparent layer, a domed wavelength-converting layer, and a second domed transparent layer with two bond wires, according to embodiments of the present invention.

FIG. 9 illustrates a cross section of a light-emitting semiconductor with a light-emitting semiconductor encapsulated by a cuboidal transparent layer disposed only above the semiconductor, a domed wavelength-converting layer, and a domed transparent layer, according to embodiments of the present invention.

FIG. 10 illustrates a cross section of a light-emitting semiconductor encapsulated by a first domed transparent layer, multiple wavelength-converting layers, and second domed transparent layer, according to embodiments of the present invention.

FIG. 11 illustrates a cross section of a light-emitting semiconductor disposed within a recessed volume of a substrate and encapsulated by a cuboidal transparent layer, a domed wavelength-converting layer, and a domed transparent layer, according to embodiments of the present invention.

FIG. 12 illustrates a cross section of a light-emitting semiconductor disposed within a recessed volume of a substrate and encapsulated by a cuboidal transparent layer, a flat wavelength-converting layer, and a domed transparent layer, according to embodiments of the present invention.

FIGS. 13-15 illustrate cross sections of a light-emitting semiconductor encapsulated by a first domed transparent layer, a domed wavelength-converting layer, and a second domed transparent layer, wherein the light-emitting semiconductor is electrically coupled to a first electrode and electrically coupled to a second electrode via a bond wire, according to embodiments of the present invention.

FIG. 16 illustrates a cross section of a through-hole light-emitting semiconductor device disposed within a recessed volume of a lead frame and encapsulated by a flat transparent layer, a domed fluorescent layer, and a domed transparent layer, according to embodiments of the present invention.

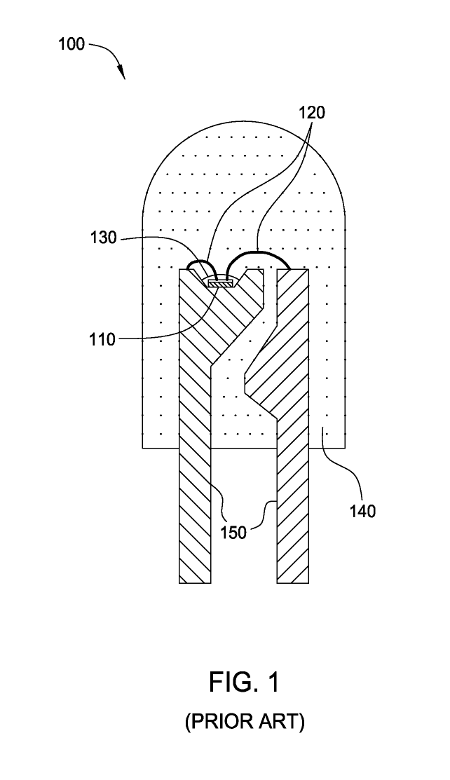

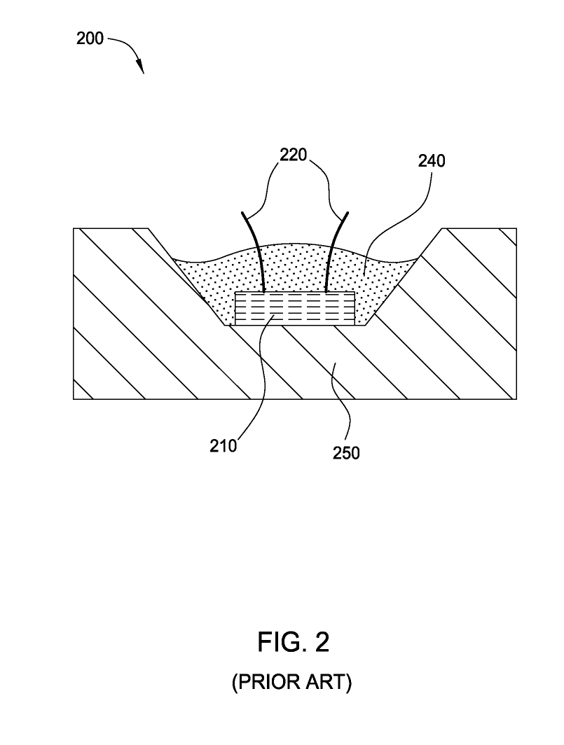

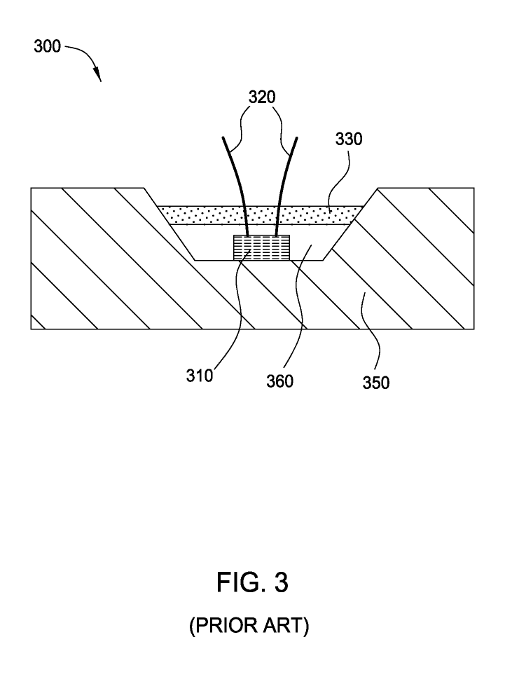

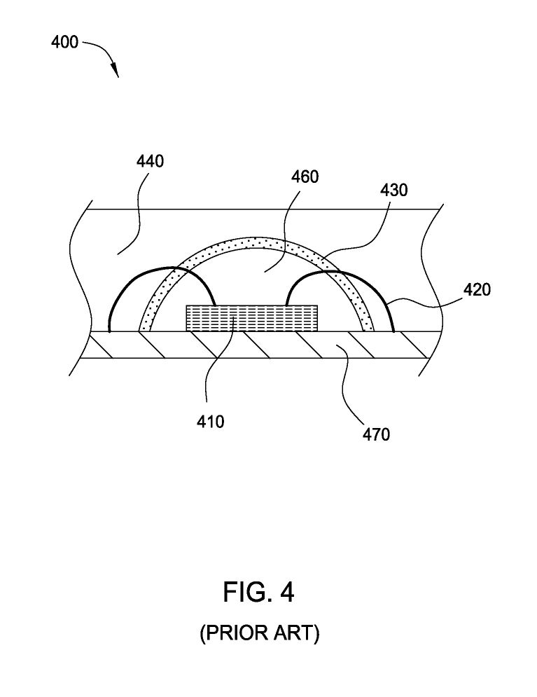

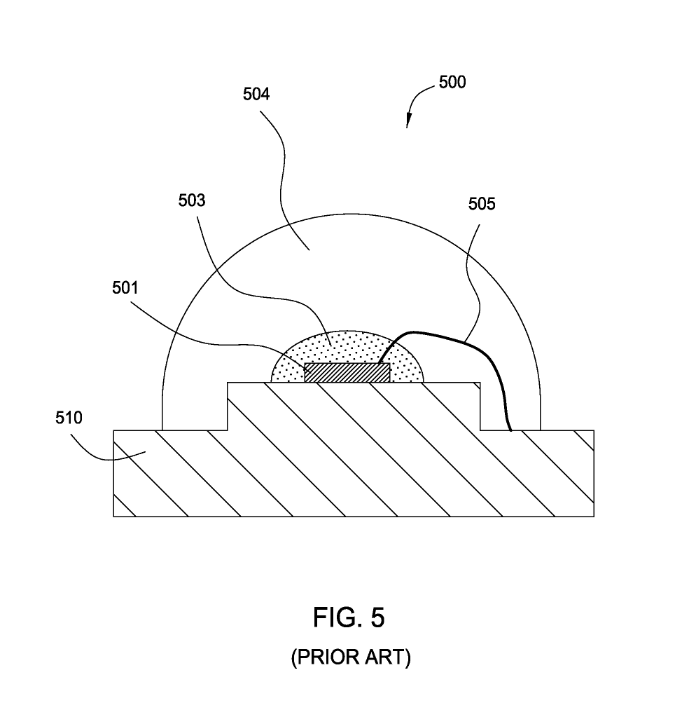

### DETAILED DESCRIPTION

Embodiments of the present invention provide light-emitting semiconductor devices with certain packaging layers arranged in an effort to produce increased luminous intensity when compared to conventional light-emitting semiconductor devices. The light-emitting semiconductor device may comprise a light-emitting semiconductor; a first transparent layer disposed over the light-emitting semiconductor; a first wavelength-converting layer disposed over the first transparent layer, wherein an upper surface of the wavelength-converting layer is curved; and a second transparent layer disposed over the wavelength-converting layer, wherein an upper surface of the second transparent layer is curved or tapered.

### An Exemplary Wavelength-Converted LED Device

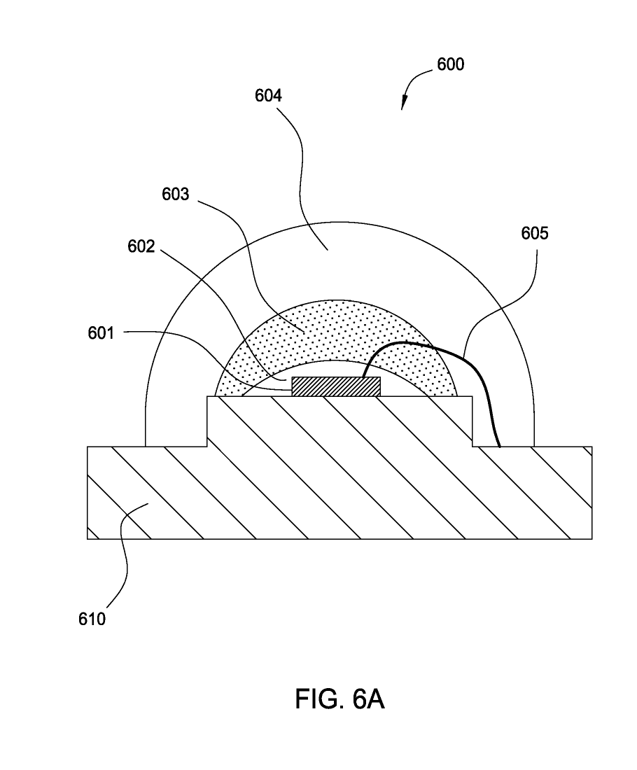

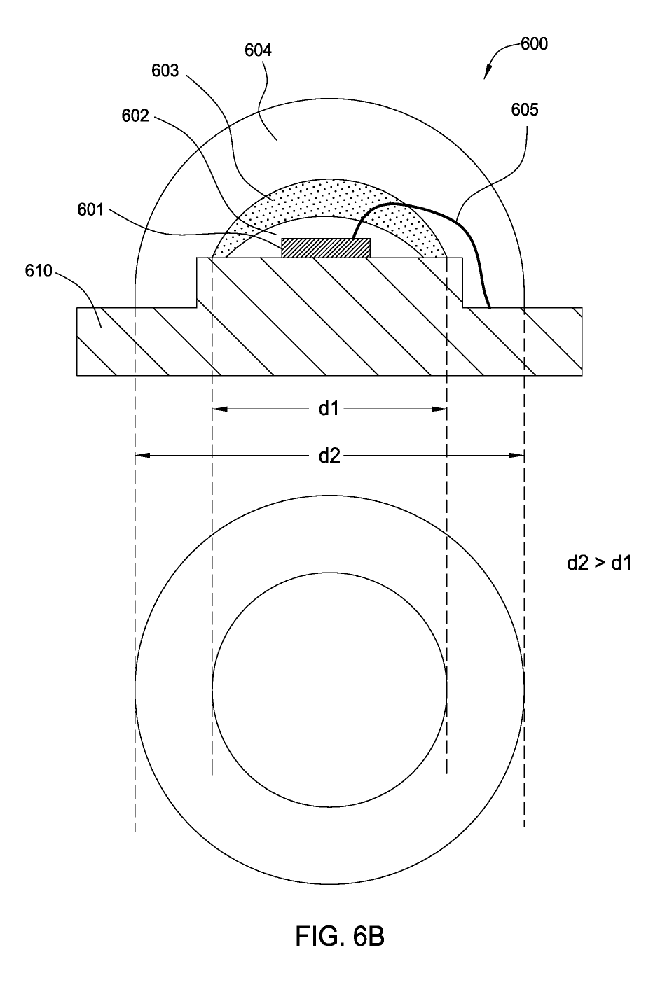

FIG. 6A depicts a light-emitting semiconductor device 600 exhibiting enhanced light extraction according to an embodiment of the invention. The light-emitting semiconductor 601 may emit light having a peak emission wavelength in the range of 200 nm to 520 nm. The light-emitting semiconductor 601 may include one or more light-emitting diode (LED) dies or laser diode dies, for example, which may be compound semiconductor dies composed of group III-group V combinations of elements, such as gallium nitride (GaN), aluminum nitride (AlN), indium nitride (InN), aluminum gallium nitride (AlGaN), and indium gallium nitride (InGaN). The light-emitting semiconductor 601 may comprise an active layer interposed between a p-doped layer and an n-doped layer such that the active layer emits light when the p-n junction is forward biased.

The light-emitting semiconductor 601 may be disposed above a substrate 610. The substrate 610 may have a flat, convex or concave shape. The substrate 610 may be a single layer or multiple layers and may be composed of any suitable material, such as Si, AlN, SiC, AlSiC, diamond, metal matrix composite (MMC), graphite, Al, Cu, Ni, Fe, Mo, CuMo, copper oxide, sapphire, glass, ceramic, metal, or a metal alloy. The light-emitting semiconductor 601 may be coupled for external connection via any suitable technique for electrical conductivity, such as soldering, bonding, or wiring with one or more bond wires 605. For example, the light-emitting semiconductor 601 in FIGS. 6A and 6B is bonded to the substrate 610 at one terminal, and the other terminal is wire bonded to another area of the substrate 610 via the bond wire 605.

For some embodiments, a reflector (not shown) may be interposed between the substrate 610 and the light-emitting semiconductor 601. The reflector may be a single layer or multiple layers and may be composed of any suitable material for reflecting light, such as Ag, Al, Rh, Ni, Au, Ni/Ag/Ni/Au, Ag/Ni/Au, Ag/Ti/Ni/Au, Al, Ti/Al, Ni/Al, Au, using an alloy containing silver, gold, Ni, Cr, Pt, Pd, Rh, Cu or Al.

For some embodiments, the light-emitting semiconductor 601 may be disposed over a lead frame instead of the substrate 610. For other embodiments, the light-emitting semiconductor 601 may be disposed over a lead frame, which is disposed above the substrate 610. The lead frame may be a single layer or multiple layers comprised of any suitable material for providing external electrical connection, such as Si, AlN, SiC, AlSiC, diamond, Al, Cu, Fe, Ni, Mo, W, CuMo, copper oxide, ceramic, metal or metal alloy. For some embodiments, the lead frame may comprise a reflector, as described above.

A first transparent layer 602 may be disposed over the one or more dies of the light-emitting semiconductor 601. The first transparent layer 602 may comprise any suitable transparent material, such as epoxy or silicone. The upper surface of the first transparent layer 602 may have a domed, convex, concave, or flat shape. The purpose of the first transparent layer 602 may be to eliminate the annular ring problem associated with some conventional LED devices.

A wavelength-converting layer 603 may be disposed over the first transparent layer 602. The wavelength-converting layer 603 may comprise a single wavelength-converting layer or multiple wavelength-converting layers. The upper surface of the wavelength-converting layer 603 may have a curved (e.g., domed or convex) or flat shape. For some embodiments, the wavelength-converting layer 603 may not have a uniform thickness.

The wavelength-converting layer 603 may convert a portion of the light emitted by the light-emitting semiconductor 601 to another wavelength. The wavelength-converting layer 603 may comprise a resin and fluorescent material, such as a phosphor powder suspended in the resin, and the weight ratio of fluorescent materials to resin may be higher than 3%. For example, the wavelength-converting layer 603 may contain phosphors responsive to most of the blue to ultraviolet (UV) light from the light-emitting semiconductor 601 to produce light wavelengths combinable with the remainder of the blue to UV light to produce white light. Therefore, this type of light-emitting semiconductor device 600 with an LED may be dubbed as a phosphor-converted LED (pcLED). The fluorescent material in the wavelength-converting layer 603 may be YAG/Gd:Ce, TAG:Ce, Silicate:Eu, calcium scandate:Ce, calcium aluminum silicon nitride:Ce or a mixture of at least two of them. The refractive index of the wavelength-converting light may most likely be less than or equal to that of the first transparent layer 602 in an effort to increase light extraction from the device 600.

A second transparent layer 604 may be disposed over the wavelength-converting layer 603. The second transparent layer 604 may be composed of any suitable transparent material, such as epoxy, silicone, polyimide, plastic, glass, quartz, an acrylic compound, PC (polycarbonate), PMMA (polymethyl methacrylate, also known as acrylic and sold by the trade name of Plexiglas), or parylene. The second transparent layer 604 may be most likely be composed of a transparent material with an equal or a lower index of refraction than that of the wavelength-converting layer 630 and that of the first transparent layer 602 in an effort to increase light extraction from the device 600. The second transparent layer 604 may comprise a single layer or multiple layers and may be characterized by a curved (e.g., domed or convex) or a tapered (e.g., conical or pyramidal) shape, for example.

A dimension of the second transparent layer 604 may be greater than a dimension of the wavelength-converting layer 603. For example, FIG. 6B illustrates that the diameter d2 of the second transparent layer 604 in the device 600 of FIG. 6A may be larger than the diameter d1 of the wavelength-converting layer 603. The ratio (d2/d1) of the diameters of the second transparent layer to the wavelength-converting layer may be greater than or equal to 1.1 for some embodiments.

When fabricating the light-emitting semiconductor device 600, the first transparent layer 602, the wavelength-converting layer 603, and the second transparent layer 604 may be successively cured using any suitable curing technique, such as an ultraviolet (UV) cure or a thermal cure via an oven or hot plate. A transparent powder may be added to any one or a combination of the first transparent layer 602, the wavelength-converting layer 603, and the second transparent layer 604 to increase the viscosity of the layer(s). The increased viscosity may facilitate the creation of the domed or convex shapes in the layer(s). The transparent powder may comprise any suitable transparent material for increasing the viscosity, such as SiO₂, Al₂O₃, quartz, MgO, ZnO, TiO₂, indium tin oxide (ITO), PMMA, and diamond.

To measure the luminous intensity of the emitted white light, the variation in the correlated color temperature (CCT) may be used. The color temperature of a light source is determined by comparing its hue with a theoretical, heated blackbody radiator. The Kelvin temperature at which the heated blackbody radiator matches the hue of the light source is that source's color temperature. An incandescent light is very close to being a blackbody radiator, but many other light sources, such as fluorescent lamps, do not emit radiation in the form of a blackbody curve and are therefore assigned what is known as a correlated color temperature (CCT). The CCT is the color temperature of a blackbody which most closely matches the light source's perceived color. The higher the Kelvin rating, the “cooler” or more blue the light. The lower the rating, the “warmer” or more yellow the light.

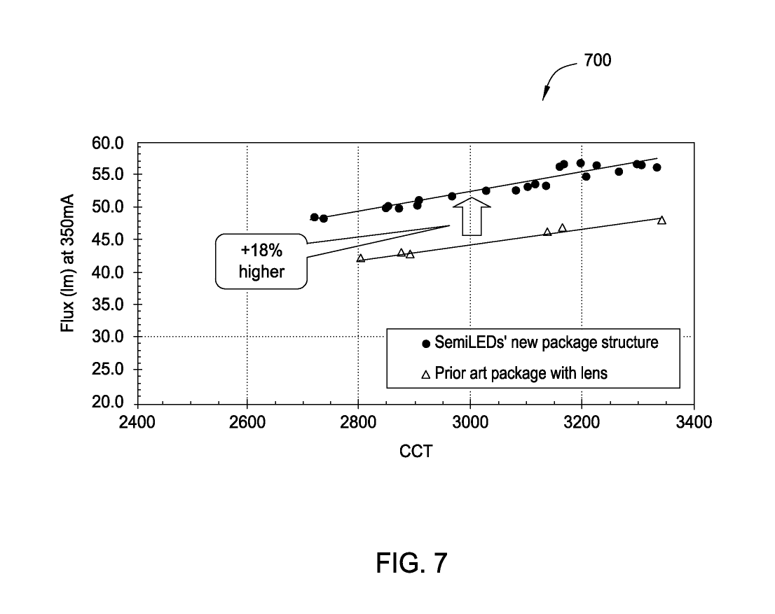

By measuring the CCT using different LED packages, the intensity of the white light produced can be quantified and compared. FIG. 7 illustrates a graph 700 of the CCT of an LED plotted against the flux in lumens of an LED at 350 mA. Embodiments of the present invention may provide up to 18% more luminous intensity when compared with conventionally packaged LEDs.

### Other Exemplary Wavelength-Converted LED Devices

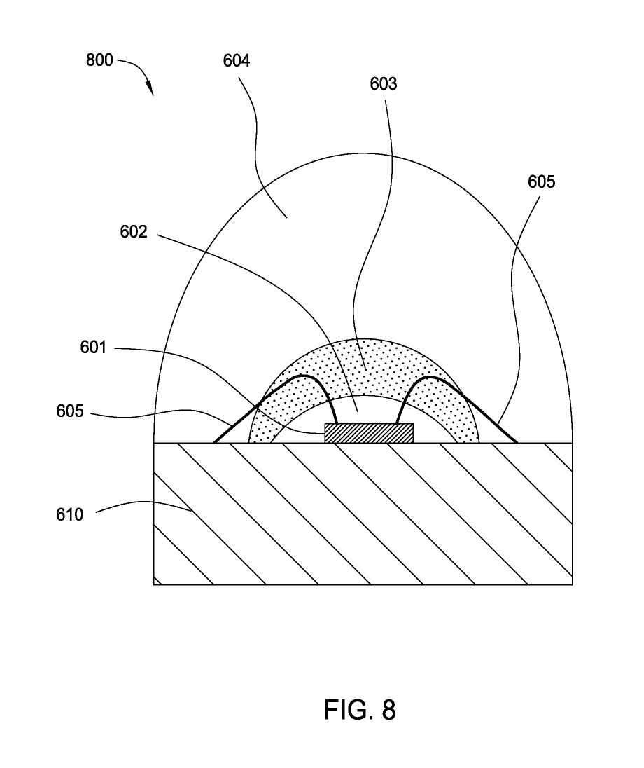

FIG. 8 illustrates a packaged light-emitting semiconductor device 800 according to an embodiment of the invention. In the device 800, the substrate 610 may have a substantially flat surface without different tiers, whereas the light-emitting semiconductor 601 of FIG. 6A is disposed above a pedestal of the substrate 610. Furthermore, the second transparent layer 604 of FIG. 8 may be shaped differently, having a height that is noticeably greater than its width with a thickness greater than that illustrated in FIG. 6A in some areas. For example, the thickness of the second transparent layer 604 at its apex is greater in FIG. 8 than in FIG. 6A. As illustrated in FIG. 8, both terminals of the light-emitting semiconductor die 601 may be coupled to the substrate 610 via two wire bonds 605.

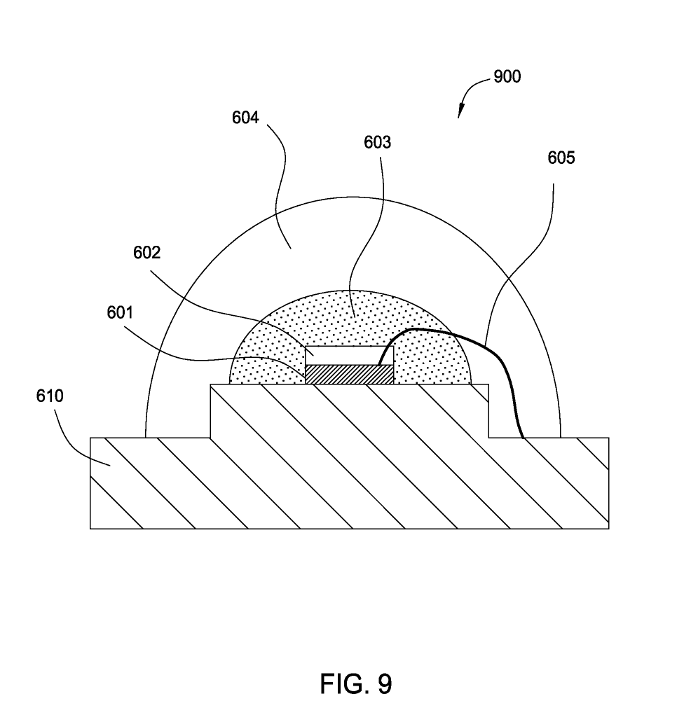

FIG. 9 illustrates a packaged light-emitting semiconductor device 900 according to an embodiment of the invention. The first transparent layer 602 may be disposed only above the light-emitting semiconductor 601 such that the first transparent layer 602 does not contact the substrate 610 and does not cover lateral surfaces of the light-emitting semiconductor 601 as illustrated. The wavelength-converting layer 603 may encapsulate the light-emitting semiconductor 601 and the first transparent layer 602. For some embodiments, the first transparent layer 602 may be cuboidal in shape as shown (rectangular or square in cross section). For other embodiments, the first transparent layer 602 disposed only above the light-emitting semiconductor 601 may have an upper surface that is domed, convex, or concave. The wavelength-converting layer 603 may contact the lateral surfaces of the light-emitting semiconductor die 601 in such embodiments as shown.

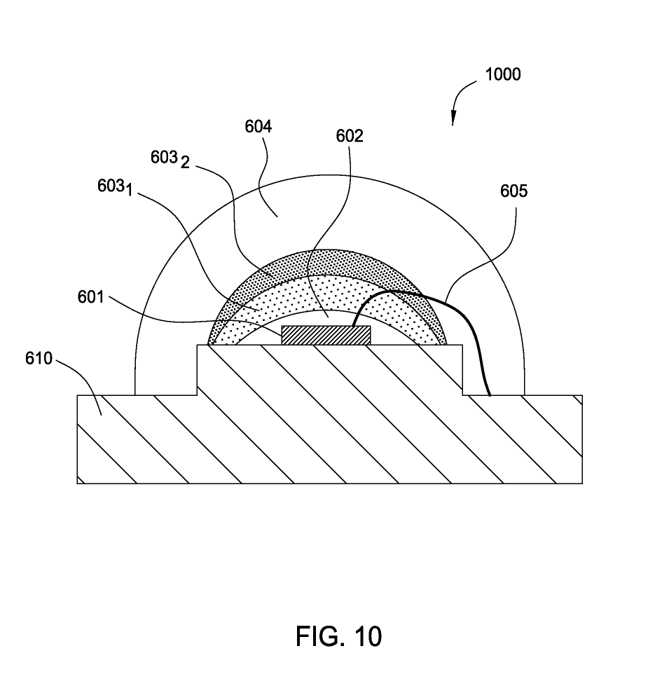

FIG. 10 illustrates a packaged light-emitting semiconductor device 1000 according to an embodiment of the invention. The device 1000 may have a wavelength-converting layer 603 comprising two or more wavelength-converting layers. For example, the device 1000 portrays a first wavelength-converting layer 603₁ and a second wavelength-converting layer 603₂ disposed above a first transparent layer 602. The thickness of either or both wavelength-converting layers 603₁, 603₂ may be non-uniform. The thicknesses of the first and second wavelength-converting layers 603₁, 603₂ may be different at corresponding points of the layers.

The first and second wavelength-converting layers 603₁, 603₂ may comprise different materials. The purpose of having more than one wavelength-converting layer may be to provide for more uniform white light. For example, the light-emitting semiconductor 601 may be a blue LED, the first wavelength-converting layer 603₁ may comprise a red phosphor, and the second wavelength-converting layer 603₂ may comprise a green phosphor.

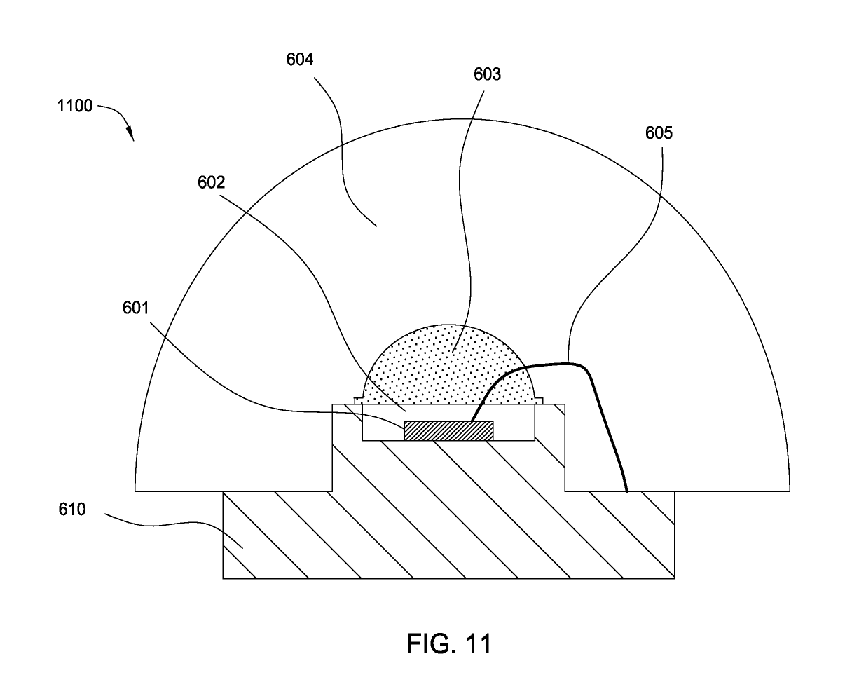

FIG. 11 illustrates a packaged light-emitting semiconductor device 1100 according to an embodiment of the invention. The substrate 610 may have a depression in which the light-emitting semiconductor 601 and at least a portion of the first transparent layer 602 are disposed. In other words, the first transparent layer 602 may be completely disposed within the depression, may completely fill and be level with the top of the depression, or may have a height greater than that of the depression. Although shown with a flat surface in FIG. 11, the upper surface of the first transparent layer may still have a domed, concave, or convex shape. Furthermore, the lateral surfaces of the depression may be vertical as shown or may be sloped. The wavelength-converting layer 603 may be disposed above the first transparent layer 602 with the wavelength-converting layer 603 completely above the depression or with at least a portion of the wavelength-converting layer 603 disposed within the depression.

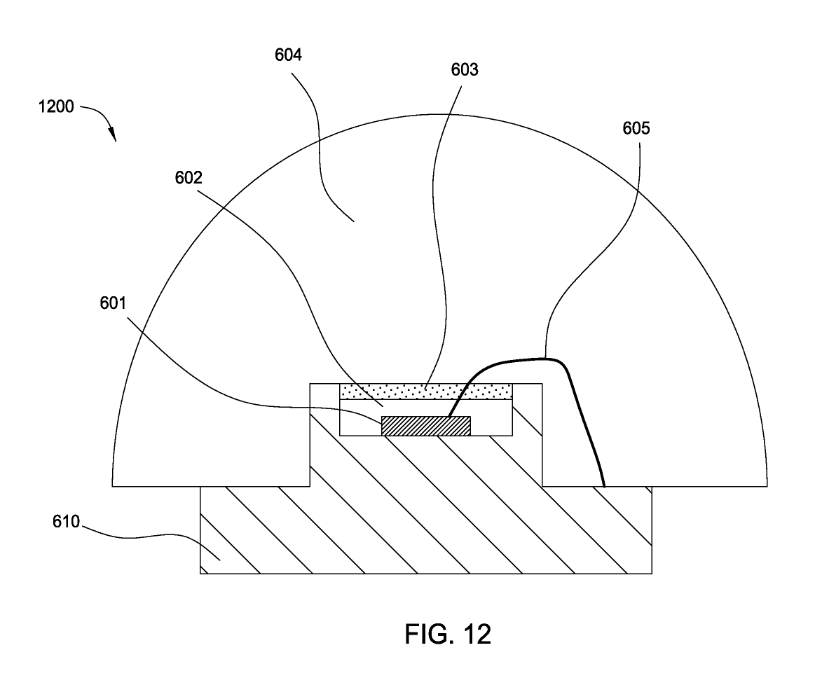

FIG. 12 illustrates a packaged light-emitting semiconductor device 1200 according to an embodiment of the invention. The device 1200 is similar to the device 1100 of FIG. 11. In device 1200, however, the first transparent layer 602 is completely disposed within the depression, and the wavelength-converting layer 603 completely fills the remainder of and is level with the top of the depression.

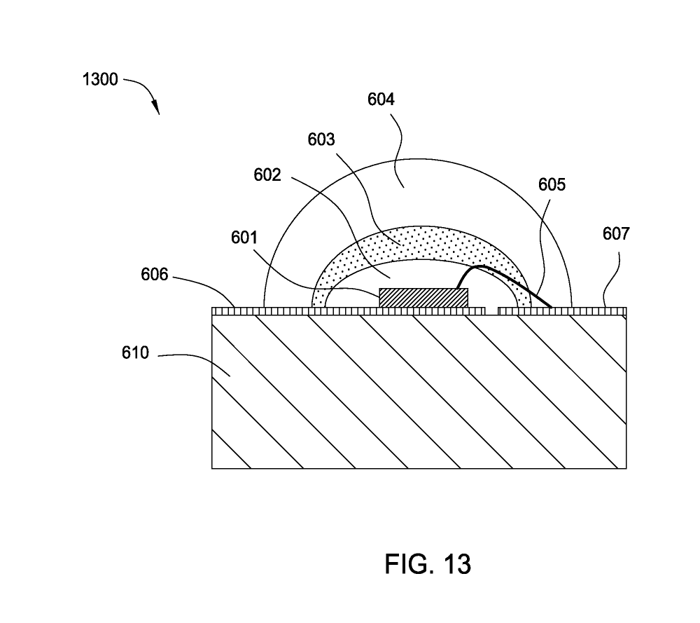

FIG. 13 illustrates a packaged light-emitting semiconductor device 1300 according to an embodiment of the invention. The substrate 610 may have a first electrode 606 of a lead frame interposed between the light-emitting semiconductor 601 and the substrate 610, and one terminal of the light-emitting semiconductor die 601 may be bonded to the first electrode 606. A second electrode 607 of the lead frame may be disposed on the substrate 610 and may be electrically coupled by wire bond 605 to the other terminal of the light-emitting semiconductor 601.

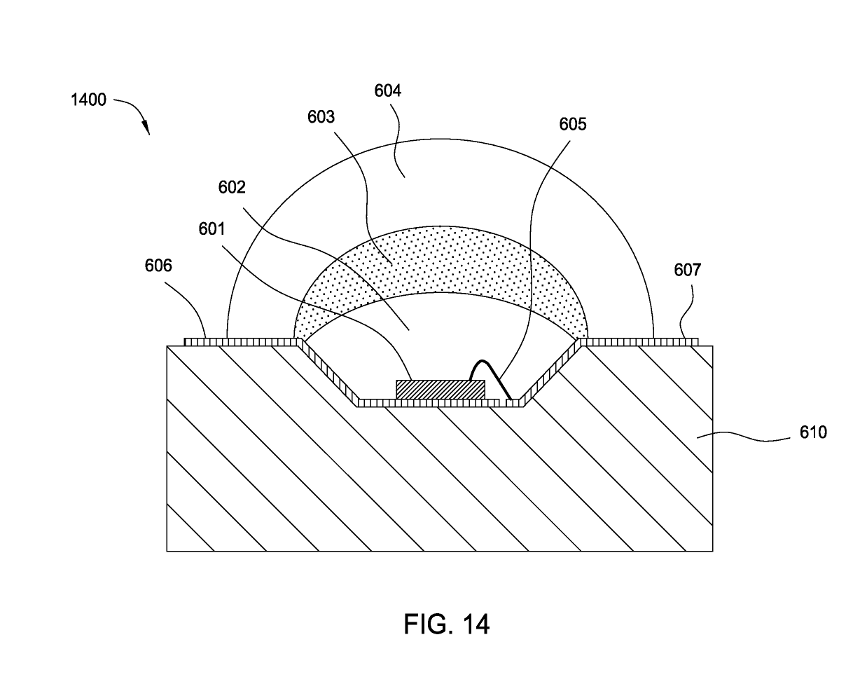

FIG. 14 illustrates a packaged light-emitting semiconductor device 1400 according to an embodiment of the invention. The device 1400 is similar to the device 1300 of FIG. 13. In device 1400, however, the substrate 610 and the lead frame may have a depression such that the light-emitting semiconductor 601 is disposed above a lower level of the first electrode 606 in the depression. The wire bond 605 may electrically couple the light-emitting semiconductor 601 to a lower level of the second electrode 607, also in the depression. As illustrated in FIG. 14, the first transparent layer 602 may completely fill the depression and rise above the height of the first and second electrodes 606, 607.

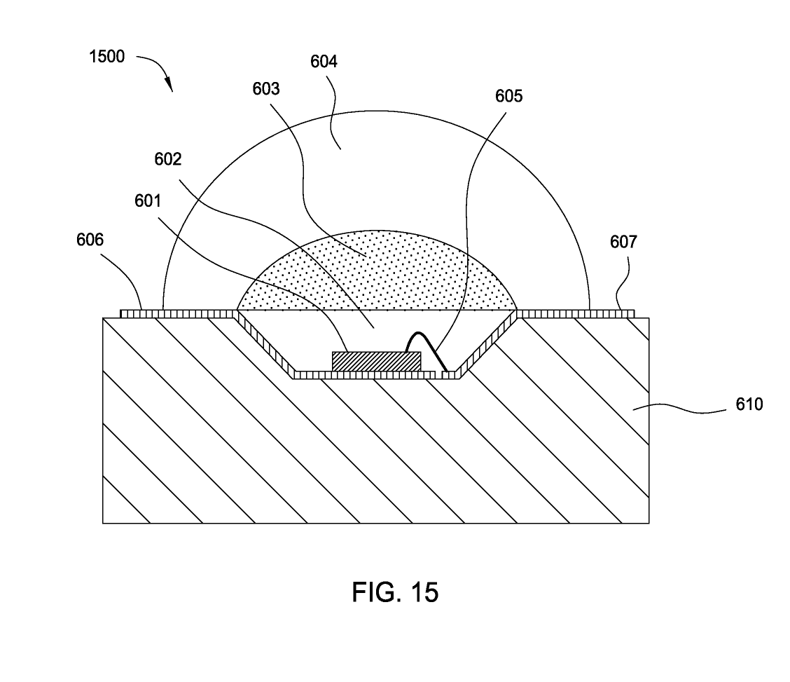

FIG. 15 illustrates a packaged light-emitting semiconductor device 1500 according to an embodiment of the invention. The device 1500 is similar to the device 1400 of FIG. 14. In device 1500, however, the upper surface of the first transparent layer 602 may be flat, and the height of the first transparent layer 602 may be even with the top of the depression and the upper level of the first and second electrodes 606,607.

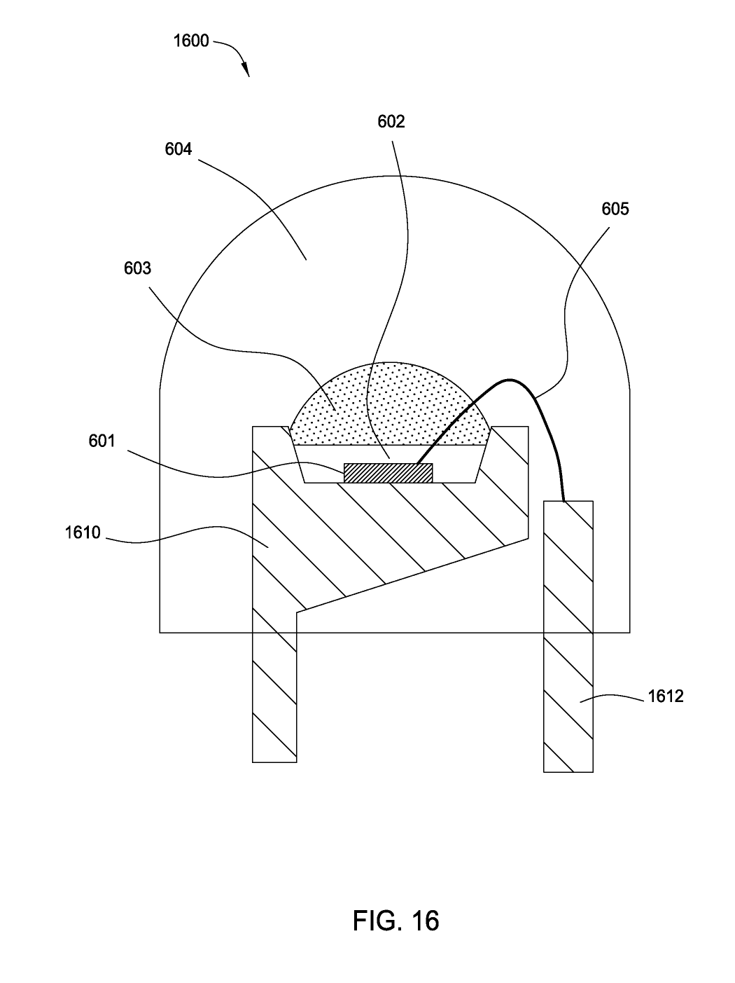

FIG. 16 illustrates a through-hole light-emitting semiconductor device 1600 according to an embodiment of the invention where the light-emitting semiconductor 601 may be installed on a lead frame 1610. The light-emitting semiconductor 601 may be disposed in a depression of the lead frame 1610. The upper surface of the first transparent layer 602 may be flat, and the first transparent layer 602 may be completely disposed within the depression for some embodiments. Furthermore, the wavelength-converting layer 603 may be partially disposed in the depression of the lead frame 1610. The wire bond 605 may be connected from one terminal of the light-emitting semiconductor 601 to a second lead 1612. The second transparent layer 604 may encapsulate part of one or more of the leads 1610,1612.

While the foregoing is directed to embodiments of the present invention, other and further embodiments of the invention may be devised without departing from the basic scope thereof, and the scope thereof is determined by the claims that follow.

1. A light-emitting device comprising:
a light-emitting semiconductor;
a first transparent layer disposed over the light-emitting semiconductor;
a first wavelength-converting layer disposed over the first transparent layer, wherein an upper surface of the wavelength-converting layer is curved; and
a second transparent layer disposed over the wavelength-converting layer, wherein an upper surface of the second transparent layer is at least one of curved or tapered.

2. The light-emitting device of claim 1, wherein the upper surface of the wavelength-converting layer is domed or convex.

3. The light-emitting device of claim 1, wherein the upper surface of the second transparent layer is domed, convex, conical, or pyramidal.

4. The light-emitting device of claim 1, wherein the wavelength-converting layer does not have a uniform thickness.

5. The light-emitting device of claim 1, further comprising a second wavelength-converting layer interposed between the first wavelength-converting layer and the second transparent layer.

6. The light-emitting device of claim 5, wherein the first and second wavelength-converting layers comprise at least one different material.

7. The light-emitting device of claim 1, wherein the light-emitting semiconductor comprises a light-emitting diode (LED) or a laser diode.

8. The light-emitting device according to claim 1, wherein the light-emitting semiconductor is configured to emit light having a peak emission wavelength in a range from 200 nm to 520 nm.

9. The light-emitting device of claim 1, wherein the first transparent layer comprises epoxy or silicone.

10. The light-emitting device of claim 1, wherein an upper surface of the first transparent layer is domed, convex, concave, or flat.

11. The light-emitting device of claim 1, wherein the first transparent layer has a higher index of refraction than the second transparent layer.

12. The light-emitting device of claim 1, wherein the first transparent layer has a higher index of refraction than the first wavelength-converting layer.

13. The light-emitting device of claim 1, wherein the first transparent layer and the first wavelength-converting layer have a higher index of refraction than the second transparent layer.

14. The light-emitting device of claim 1, wherein the first wavelength-converting layer comprises a resin and a fluorescent material and a weight ratio of the fluorescent material to the resin is higher than 3%.

15. The light-emitting device of claim 1, wherein the first wavelength-converting layer comprises at least one of YAG/Gd:Ce, TAG:Ce, silicate:Eu, calcium scandate:Ce, or calcium aluminum silicon nitride:Ce.

16. The light-emitting device of claim 1, wherein the light-emitting semiconductor produces blue light and the first wavelength-converting layer comprises a phosphor responsive to the blue light to produce light combinable with the blue light to produce white light therefrom.

17. The light-emitting device of claim 1, wherein the light-emitting semiconductor produces ultraviolet (UV) light and the first wavelength-converting layer comprises a phosphor responsive to the UV light to produce light combinable with the UV light to produce white light therefrom.

18. The light-emitting device of claim 1, wherein the second transparent layer comprises at least one of epoxy, silicone, polyimide, plastic, glass, quartz, an acrylic compound, PC (polycarbonate), PMMA (polymethyl methacrylate), or parylene.

19. The light-emitting device of claim 1, wherein the second transparent layer comprises multiple layers.

20. The light-emitting device of claim 1, wherein a dimension of the second transparent layer is greater than a dimension of the first wavelength-converting layer.

21. The light-emitting device of claim 20, wherein a ratio of the diameter of the second transparent layer to the diameter of the first wavelength-converting layer is at least 1.1.

22. The light-emitting device of claim 1, wherein at least one of the first transparent layer, the first wavelength-converting layer, and the second transparent layer comprises a transparent powder to increase the viscosity of the at least one layer for fabrication.

23. The light-emitting device of claim 22, wherein the transparent powder comprises at least one of SiO₂, Al₂O₃, quartz, MgO, ZnO, TiO₂, indium tin oxide (ITO), polymethyl methacrylate (PMMA), and diamond.

24. The light-emitting device of claim 1, wherein the light-emitting semiconductor is disposed above a substrate.

25. The light-emitting device of claim 1, further comprising a reflector interposed between the substrate and the light-emitting semiconductor.

26. The light-emitting device of claim 1, wherein the light-emitting semiconductor is disposed above a lead frame.

27. The light-emitting device of claim 1, wherein the lead frame is disposed above a substrate.
